(19) United States
(12) Patent Application Publication
(10) Pub. No.: US 2014/0284558 A1
(43) Pub. Date: Sep. 25, 2014

(54) THIN FILM TRANSISTOR AND ORGANIC LIGHT EMITTING DIODE DISPLAY INCLUDING THE SAME

(71) Applicant: Samsung Display Co., Ltd., Yongin-City (KR)

(72) Inventors: Tae-Hoon Yang, Yongin-City (KR); Bo-Kyung Choi, Yongin-City (KR); Jae-Wan Jung, Yongin-City (KR); Ki-Yong Lee, Yongin-City (KR)

(73) Assignee: Samsung Display Co., Ltd., Yongin-City (KR)

(21) Appl. No.: 13/933,057

(22) Filed: Jul. 1, 2013

(30) Foreign Application Priority Data
Mar. 20, 2013 (KR) 1020130029969

(51) Int. Cl. H01L 27/32

(52) U.S. Cl. CPC H01L 27/3262
USPC 257/40; 257/66

(57) ABSTRACT

A thin film transistor (TFT) includes a semiconductor on a substrate; an ohmic contact overlapping at least a portion of the semiconductor; a source electrode and a drain electrode on the ohmic contact; a gate insulating layer covering the semiconductor; and a gate electrode overlapping the semiconductor and between the source electrode and the drain electrode on the gate insulating layer, wherein the gate electrode is laterally separated from the drain electrode by a first distance and is laterally separated from the source electrode by a second distance.

### CROSS-REFERENCE TO RELATED APPLICATION

This application claims priority to and the benefit of Korean Patent Application No. 10-2013-0029969, filed in the Korean Intellectual Property Office on Mar. 20, 2013, the entire content of which is incorporated herein by reference.

### BACKGROUND

1. Field

The described technology relates generally to a thin film transistor and an organic light emitting diode (OLED) display including the same.

2. Description of the Related Art

Thin film transistors (TFT) are used in various fields and are particularly used as switching and driving elements in flat panel displays such as liquid crystal displays (LCD), organic light emitting diode (OLED) displays, and electrophoretic displays.

A thin film transistor may include a gate electrode coupled to a gate line for transmitting a scan signal, a source electrode coupled to a data line for transmitting a signal to be applied to a pixel electrode, a drain electrode that faces the source electrode, and a semiconductor electrically coupled to the source electrode and the drain electrode.

The semiconductor of the thin film transistor is formed of amorphous silicon or crystalline silicon. Amorphous silicon may be deposited at low temperature to form a thin film and is widely used for a display device in which glass having a low melting point is used in a substrate. Crystalline silicon may have a relatively high electric field effect mobility, a relatively high frequency operation characteristic, and an electric characteristic of relatively low leakage current.

However, due to a relatively low electric field effect mobility of bottom gate structured amorphous silicon thin films, it may be difficult to enlarge an area of a display element. Additionally, a top gate structured thin film transistor using crystalline silicon may have a relatively complicated crystallizing process.

The above information disclosed in this Background section is only for enhancement of understanding of the background of the described technology and therefore it may contain information that does not form the prior art that is already known in this country to a person of ordinary skill in the art.

### SUMMARY

A top gate staggered structured gate electrode may overlap a source electrode and a drain electrode so that the gate electrode is positioned on the source electrode and the drain electrode to generate a current crowding phenomenon.

Therefore, a technical aspect of the present invention is to provide a TFT in which a current crowding phenomenon is not generated in a top gate staggered structure and an OLED display including the same.

A TFT according to an embodiment of the present invention includes a semiconductor on a substrate; an ohmic contact overlapping at least a portion of the semiconductor; a source electrode and a drain electrode on the ohmic contact; a gate insulating layer covering the semiconductor; and a gate electrode overlapping the semiconductor and between the source electrode and the drain electrode on the gate insulating layer, wherein the gate electrode is laterally separated from the drain electrode by a first distance and is laterally separated from the source electrode by a second distance.

The first distance and the second distance may be no less than 0 μm and no more than 10 μm.

The first distance and the second distance may be no less than 0 μm and no more than 2 μm.

The TFT may further include an etch stop layer at the semiconductor between the source electrode and the drain electrode.

The source electrode and the drain electrode may follow the contours of the ohmic contact.

The ohmic contact may follow the contours of the semiconductor excluding a channel between the source electrode and the drain electrode.

An OLED display according to an embodiment of the present invention includes a substrate; a TFT on the substrate; a first electrode coupled to the TFT; a light emitting layer on the first electrode; and a second electrode on the light emitting layer, wherein a gate electrode of the TFT is laterally separated from a drain electrode by a first distance and is laterally separated from a source electrode by a second distance.

The TFT may include a semiconductor on the substrate, an ohmic contact overlapping at least a portion of the semiconductor; the source electrode and the drain electrode on the ohmic contact; a gate insulating layer covering the semiconductor; and the gate electrode overlapping the semiconductor between the source electrode and the drain electrode on the gate insulating layer.

The first distance and the second distance may be no less than 0 μm and no more than 10 μm.

The first distance and the second distance may be no less than 0 μm and no more than 2 μm.

The OLED display may further include an encapsulation member on the second electrode, and wherein the encapsulation member comprises at least one inorganic layer and at least one organic layer.

When the TFT, and the OLED display including the same, is formed by the method according to embodiments of the present invention, it may be possible to provide the TFT in which the current crowding phenomenon may not be generated or the current crowding phenomenon may be reduced.

### BRIEF DESCRIPTION OF THE DRAWINGS

FIG. 1 is a top plan view of a thin film transistor according to an embodiment.

FIG. 2 is a cross-sectional view taken along the line II-II of FIG. 1.

FIGS. 3 to 6 are graphs measuring ion characteristics in accordance with offset distances.

FIGS. 7 to FIG. 9 are graphs specifying voltage and current characteristics in accordance with offset distances.

FIGS. 10 and 11 are cross-sectional views describing a method of manufacturing a thin film transistor according to an embodiment.

FIGS. 12 and 13 are cross-sectional views describing a method of manufacturing a thin film transistor according to another embodiment.

FIG. 14 is a cross-sectional view of a thin film transistor according to another embodiment.

FIGS. 15 and 16 are cross-sectional views describing a method of manufacturing a thin film transistor according to another embodiment.

FIG. 17 is an equivalent circuit diagram of a pixel of an organic light emitting diode (OLED) display according to another embodiment.

FIG. 18 is a cross-sectional view of a pixel of the OLED display of FIG. 17.

### DETAILED DESCRIPTION

Embodiments of the present invention will be described more fully hereinafter with reference to the accompanying drawings. As those skilled in the art would realize, the described embodiments may be modified in various different ways, all without departing from the spirit or scope of the present invention.

In the drawings, the thickness of layers, films, panels, regions, etc., may be exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, a thin film transistor (TFT) according to an embodiment of the present invention will be described with reference to the following drawings.

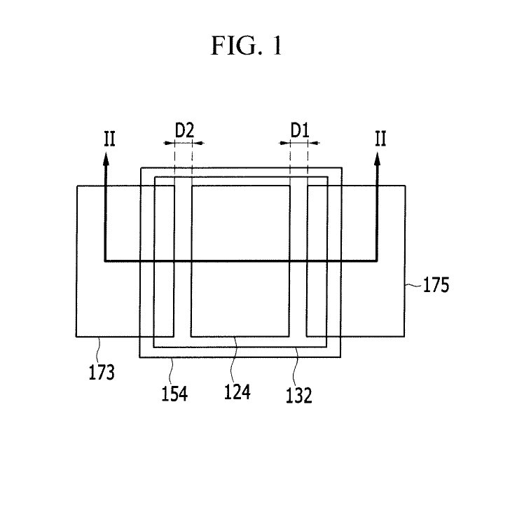

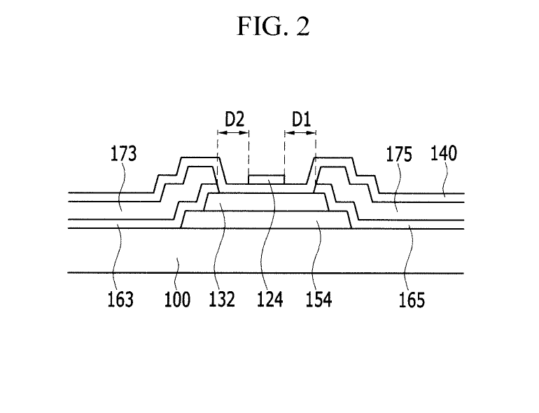

FIG. 1 is a top plan view of a TFT according to an embodiment and FIG. 2 is a cross-sectional view taken along the line II-II of FIG. 1.

As shown in FIGS. 1 and 2, the TFT includes a semiconductor 154 positioned on a substrate 100, an etch stop layer 132 positioned on the semiconductor 154, an ohmic contact 165 positioned on the etch stop layer 132, a source electrode 173 and a drain electrode 175 positioned on the ohmic contact 165, a gate insulating layer 140 positioned on the source electrode 173 and the drain electrode 175, and a gate electrode 124 positioned on the gate insulating layer 140.

The substrate 100 may be formed of any suitable substrate material, and may include the materials of which the TFT may be formed such as glass, metal, and a flexible polymer material.

The polymer material may be an insulating organic material and may be an organic material selected from the group consisting of polyethersulphone (PES), polyacrylate (PAR), polyetherimide (PEI), polyethyelenen napthalate (PEN), polyethyeleneterepthalate (PET), polyphenylene sulfide (PPS), polyallylate, polyimide, polycarbonate (PC), cellulose triacetate (TAC), and cellulose acetate propionate (CAP).

The semiconductor 154 may be formed of amorphous silicon (a-Si). In addition, the semiconductor layer 154 may be formed of polysilicon or an oxide semiconductor. The oxide semiconductor may include one of an oxide based on Zn, Ga, Sn, or In, ZnO that is a composite oxide of Zn, Ga, Sn, and In, InGaZnO₄, Zn—In—O, and Zn—Sn—O.

In one embodiment, when the semiconductor layer 154 is formed of crystalline silicon, the semiconductor layer 154 includes a channel region that is not doped with impurities and a source region and a drain region doped with impurities on both sides of the channel region. Here, the impurities vary with a kind of the TFT and N-type impurities or P-type impurities may be used.

When the semiconductor layer 154 is formed of the oxide semiconductor, an additional protective layer may be added in order to protect the oxide semiconductor from exposure to high temperatures and external environmental conditions or contaminants.

The etch stop layer 132 for preventing the semiconductor from being damaged during etching may be formed of any suitable etch stop layer material such as silicon oxide or silicon nitride.

The ohmic contacts 163 and 165 may be formed of any suitable ohmic contact material such as n+ amorphous silicon hydride highly doped with n-type impurities such as P or silicide.

The source electrode 173 and the drain electrode 175 have the same plane pattern as that of the ohmic contacts 163 and 165. That is, the source electrode 173 and the drain electrode 175 may be formed or positioned over the ohmic contacts 163 and 165 such that the source electrode 173 and the drain electrode 175 follow the contours of the ohmic contacts 163 and 165, respectively. The source electrode 173 and the drain electrode 175 may be a single layer or a plurality of layers formed of any suitable conductive material or metal such as copper, aluminum, tungsten, and titanium or an alloy of the above metals.

The gate insulating layer 140 covers or extends over the channel region of the semiconductor 154 and may be an inorganic layer formed of silicon nitride or silicon oxide.

The gate electrode 124 may be a single layer or a plurality of layers formed of the same metal or alloy as that of the source electrode 173 and the drain electrode 175.

The gate electrode 124 is positioned on or over the semiconductor 154, and is positioned laterally between the source electrode 173 and the drain electrode 175 that face each other.

A channel of the TFT is formed in the semiconductor 154 between the source electrode 173 and the drain electrode 175.

Offsets are formed between the gate electrode 124 and the source electrode 173 and between the gate electrode 124 and the drain electrode 175. That is, the gate electrode 124 and the drain electrode 175 are laterally separated from each other by a first distance D1, and the gate electrode 124 and the source electrode 173 are laterally separated from each other by a second distance D2.

The first distance D1 and the second distance D2 that form the offsets may be no less than 0 μm and no more than 10 μm and in one embodiment is no less than 0 μm and no more than 2 μm.

In one embodiment, the first distance and the second distance D are no less than 0 μm, but may have an error of 1 μm in accordance with resolution of an exposer during patterning.

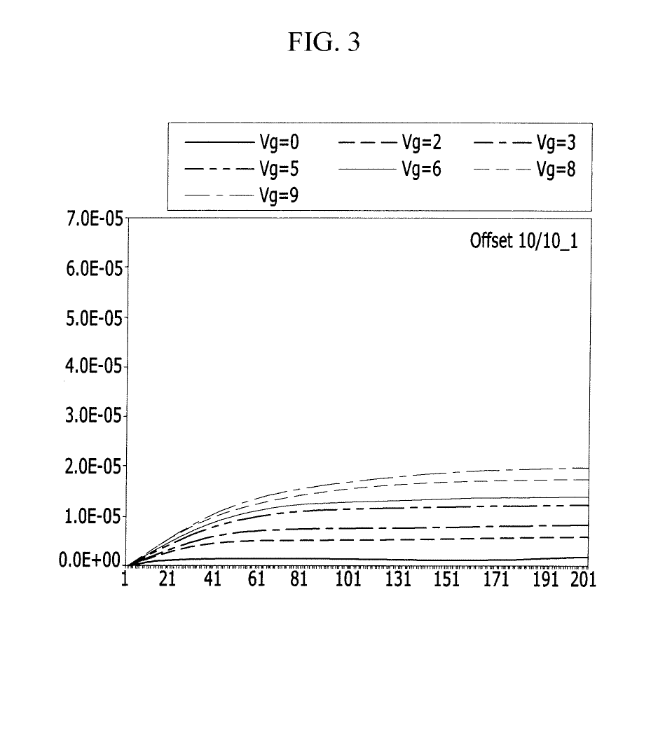

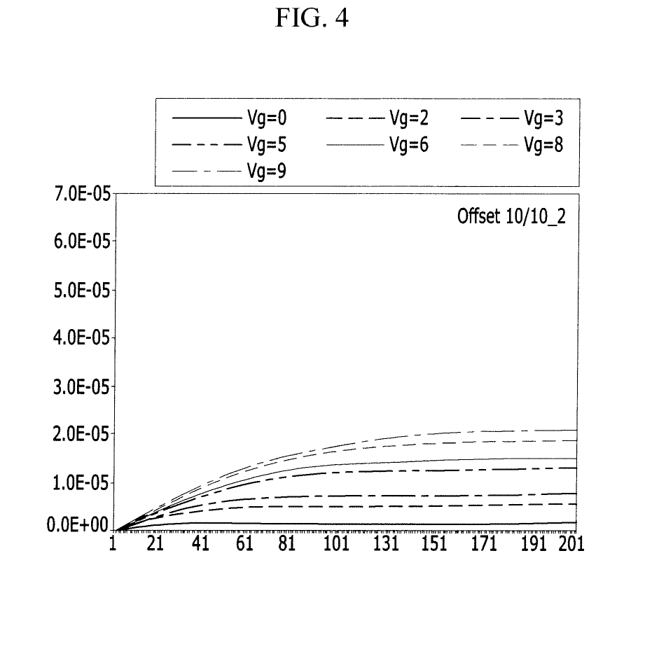

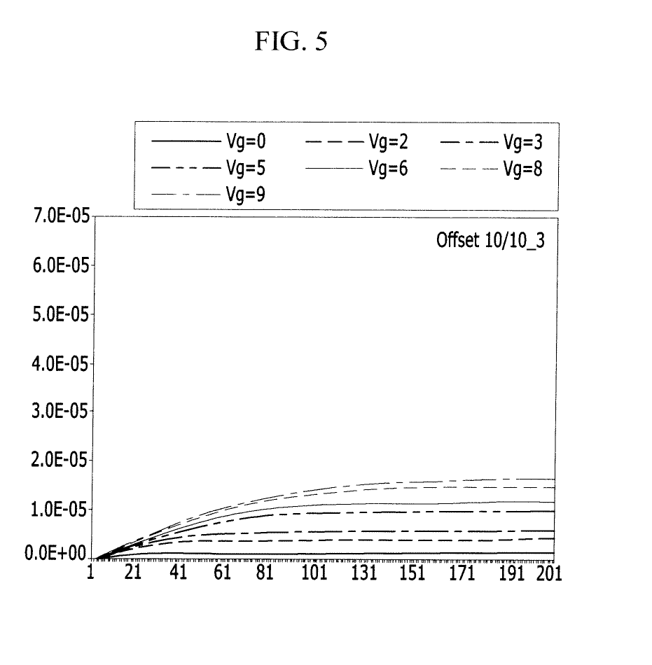

FIGS. 3 to 6 are graphs measuring ion characteristics in accordance with offset distances.

In FIGS. 3 to 6, the offset distances D1 and D2 are 1 μm, 2 μm, 3 μm, and −2 μm, respectively (− means that the drain electrode or the source electrode overlaps the gate electrode).

As shown in FIGS. 3 to 5, although the offset distances are increased to 1 μm, 2 μm, and 3 μm, respectively, a current crowding phenomenon is not generated.

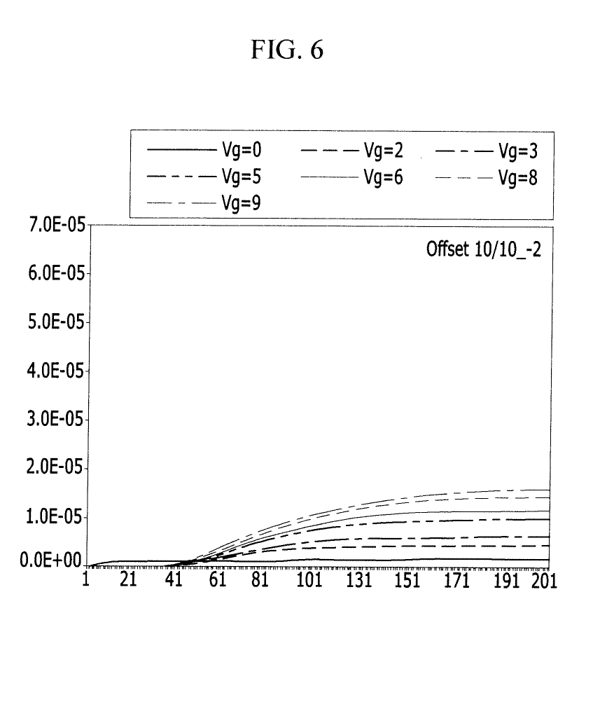

However, as shown in FIG. 6, when the offset distance is −2 μm, that is, when the drain electrode (or the source electrode) overlaps the gate electrode, the current crowding phenomenon is generated.

As described above, although the offset distance is increased, the current crowding phenomenon is not generated. However, when a size of a channel that is a distance between the source electrode and the drain electrode is limited and the gate electrode is formed to have a size of no less than a uniform size, the offset distance is no more than 10 μm.

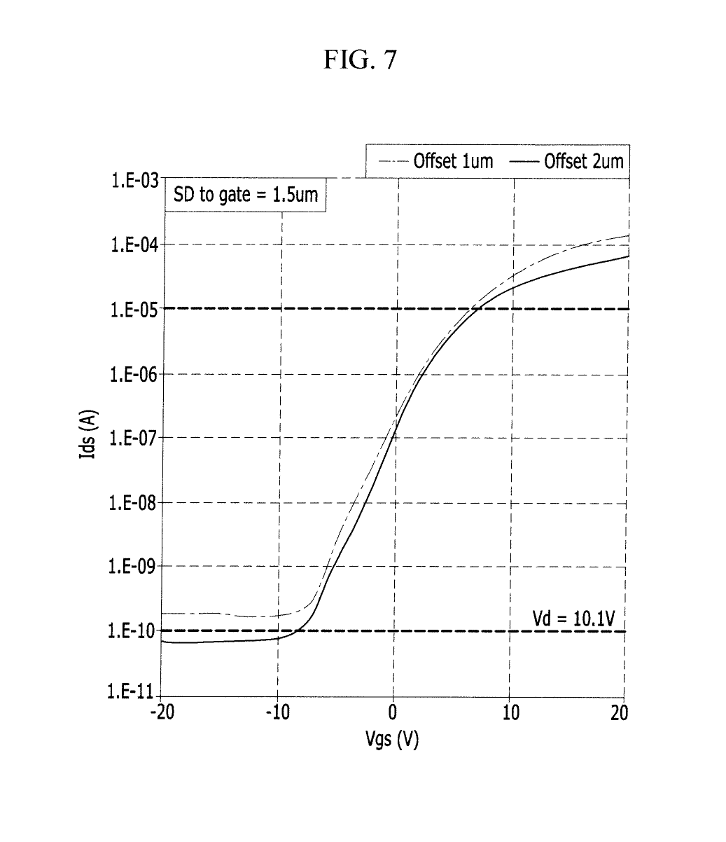

FIGS. 7 to 9 are graphs specifying voltage and current characteristics in accordance with offset distances.

In FIGS. 7 to 9, the drain electrode and the gate electrode are separated from each other by the first distance D1, and the source electrode and the gate electrode are separated from each other by the second distance D2.

In FIGS. 7 to 9, the second distances are 1.5 μm, 0 μm, and −1.5 μm, respectively. In each of FIGS. 7 to 9, the voltage and current characteristics are shown with the first distance D1 being both 1 μm and 2 μm. In order to facilitate comparison, a reference value of an off current is set as 1×10⁻¹⁰ (1.E-10) Amperes (A) and that of an on current is set as 1×10⁻⁵ (1.E-5) A.

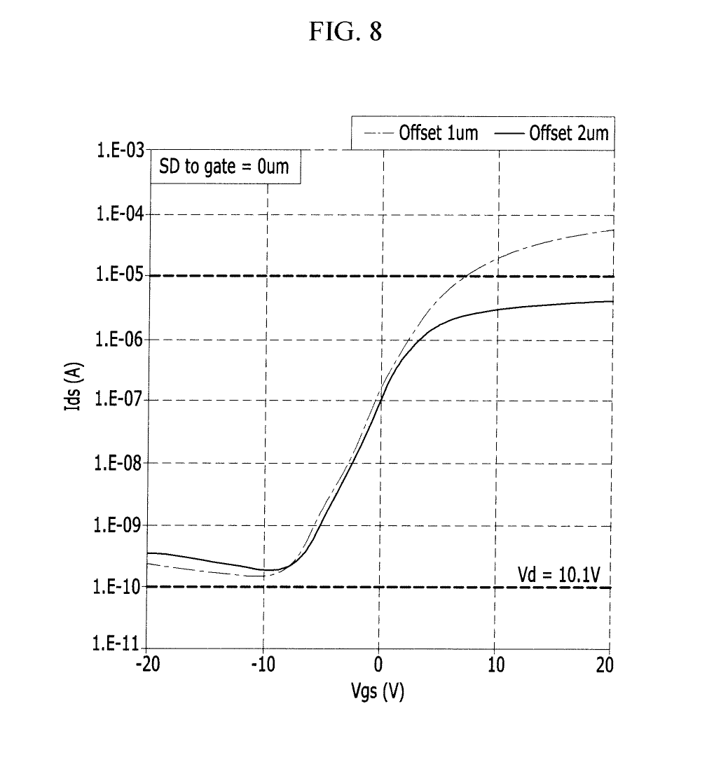

Referring to FIG. 7, when the second distance D2 is 1.5 μm and the first distances are 1 μm and 2 μm, all of the on current values are larger than the reference value. Referring to FIG. 8, when the second distance D2 is 0 μm, all of the on current values are larger than the reference value when the first distance D1 is 1 μm, but the on current values are smaller than the reference value when the first distance D1 is 2 μm.

It is noted that a current characteristic of the TFT is improved when the second distance and the first distance have suitable values.

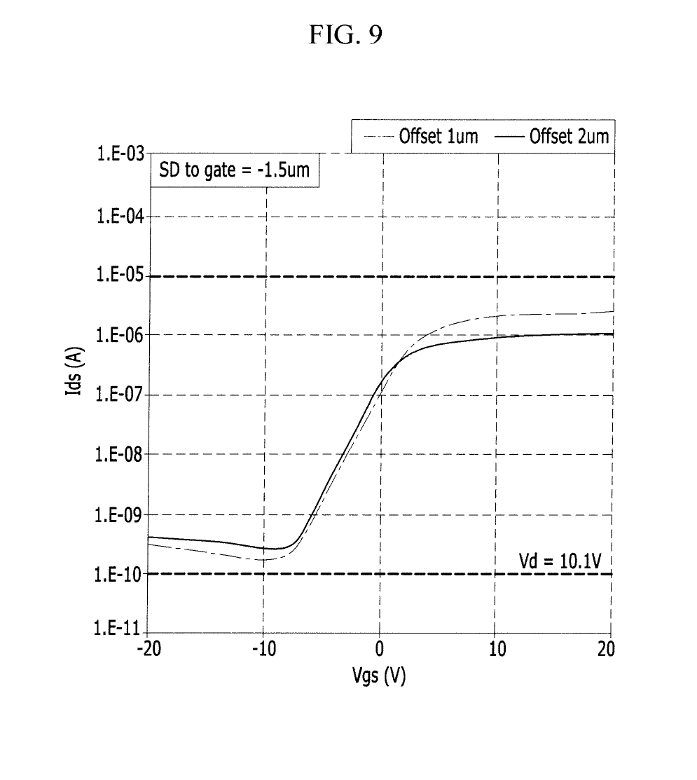

On the other hand, referring to FIG. 9, the second distance is −1.5 μm and the first distance D1 is either 1 μm or 2 μm. As described above, when the source electrode and the gate electrode overlap each other by 1.5 μm, although the offset by the first distance such as 1 μm and 2 μm is formed between the drain electrode and the gate electrode, a current value is smaller than the reference value.

As described above, when the first distance and the second distance are greater than or equal to 0 μm, because it is possible to minimize or reduce an influence that the source electrode and the drain electrode have on an electric field formed in the gate electrode, it is possible to prevent or substantially prevent the current crowding phenomenon from being generated.

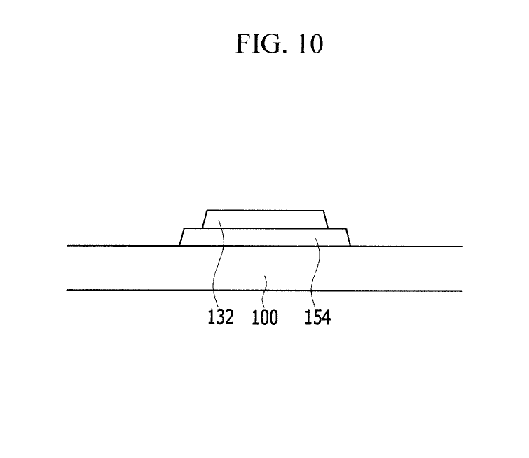

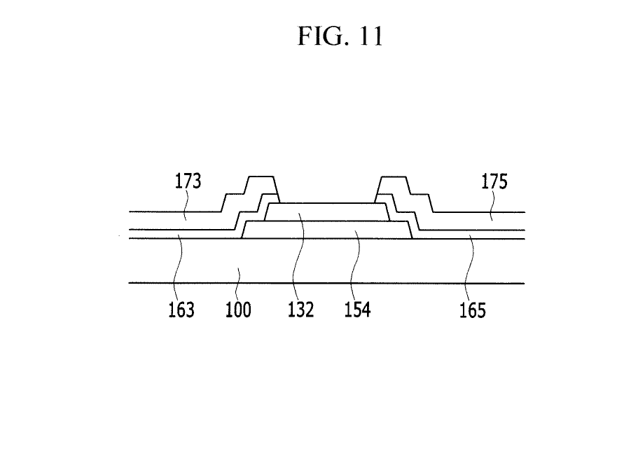

The method of manufacturing the TFT will be described in more detail with reference to FIGS. 10 and 11 and above-described FIG. 2.

FIGS. 10 and 11 are cross-sectional views describing a method of manufacturing a TFT according to an embodiment.

As shown in FIG. 10, after forming an amorphous silicon layer by depositing amorphous silicon on the substrate 100, the amorphous silicon layer is patterned to form the semiconductor 154.

Then, after forming a silicon nitride layer on the semiconductor 154, the silicon nitride layer is patterned to form the etch stop layer 132.

Next, as shown in FIG. 11, an amorphous silicon layer and a conductive or metal layer doped with impurities are formed on the semiconductor 154.

Then, the conductive or metal layer and the amorphous silicon layer are etched by a photolithography process to form the source electrode 173 and the drain electrode 175, and the ohmic contacts 163 and 165, respectively.

Because the source electrode 173 and the drain electrode 175 and the ohmic contacts 163 and 165 are simultaneously or concurrently etched, the source electrode 173 and the drain electrode 175 and the ohmic contacts 163 and 165 have the same plane pattern. That is, the source electrode 173 and the drain electrode 175 follow the contours of the ohmic contacts 163 and 165, respectively.

At this time, because the semiconductor 154 positioned between the source electrode 173 and the drain electrode 175 is covered with the etch stop layer 132, the semiconductor 154 is not exposed to an etching process so that a surface of the semiconductor is protected during the etching process.

Next, as shown in FIG. 2, the gate insulating layer 140 that covers the source electrode 173 and the drain electrode 175 and the etch stop layer 132 is formed.

After forming a conductive or metal layer on the gate insulating layer 140, the conductive or metal layer is patterned to form the gate electrode 124.

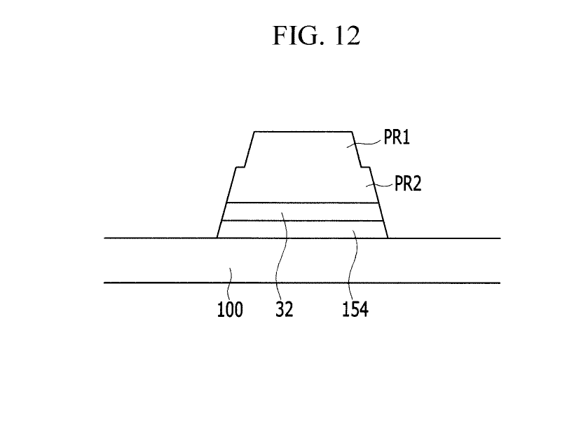

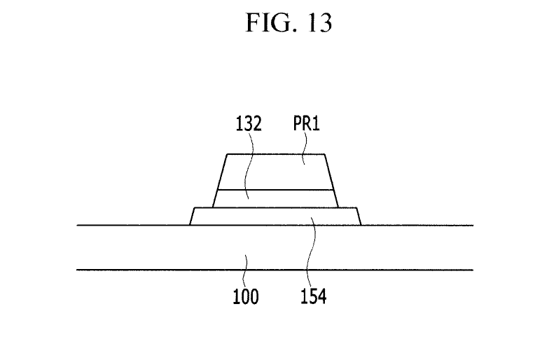

Unlike in the above-described embodiment, the etch stop layer and the semiconductor may be formed by performing a patterning process once. That is, as shown in FIGS. 12 and 13, and in one embodiment, the amorphous silicon layer and a nitride layer as the etch stop layer are laminated to form the etch stop layer and the semiconductor using a photosensitive layer pattern having different thicknesses.

FIGS. 12 and 13 are cross-sectional views describing a method of manufacturing a TFT according to another embodiment.

For example, as shown in FIG. 12, the amorphous silicon layer and the silicon nitride layer are laminated. A photosensitive layer pattern including a first photosensitive pattern and a second photosensitive pattern having different thicknesses is formed. The first photosensitive pattern PR1 is formed to be thicker than the second photosensitive pattern PR2.

Then, the silicon nitride layer and the amorphous silicon layer are etched using the photosensitive layer pattern as a mask to form a silicon nitride pattern 32 and the semiconductor 154.

Next, as shown in FIG. 13, after removing the second photosensitive pattern, the silicon nitride pattern is etched using the first photosensitive pattern PR1 as a mask to form the etch stop layer 132. When the second photosensitive pattern is removed, the first photosensitive pattern may be partially removed.

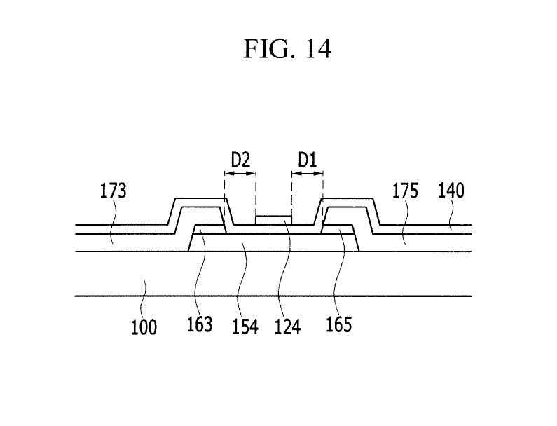

FIG. 14 is a cross-sectional view of a TFT according to another embodiment.

Because the TFT of FIG. 14 is substantially the same as that of FIG. 2, some of the different parts will be described in detail and descriptions of similar elements will be omitted.

As shown in FIG. 14, a TFT according to another embodiment includes the semiconductor 154 formed on the substrate 100, the ohmic contacts 163 and 165 formed on the semiconductor 154, the source electrode 173 and the drain electrode 175 positioned on the ohmic contacts 163 and 165, the gate insulating layer 140 positioned on the source electrode 173 and the drain electrode 175, and the gate electrode 124 positioned on the gate insulating layer 140.

Unlike the TFT of FIG. 2, that of FIG. 14 does not include the etch stop layer.

The ohmic contacts 163 and 165 have the same plane pattern as that of the semiconductor 154 excluding a channel between the source electrode 173 and the drain electrode 175.

Hereinafter, a method of manufacturing the TFT of FIG. 14 will be described in more detail.

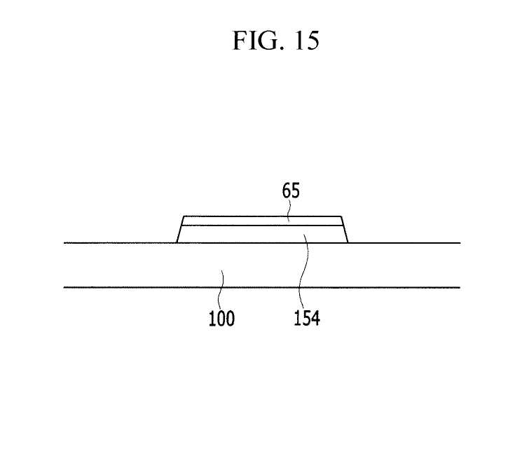

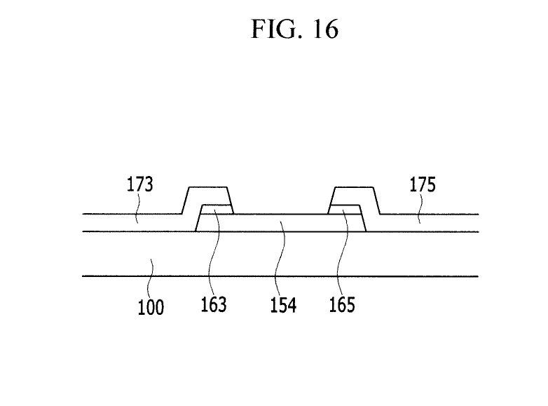

FIGS. 15 and 16 are cross-sectional views describing a method of manufacturing a TFT according to another embodiment.

As shown in FIG. 15, after laminating a first amorphous silicon layer and a second amorphous silicon layer on the substrate 100, the second amorphous silicon layer and the first amorphous silicon layer are patterned by a photolithography process to form an ohmic contact pattern 65 and the semiconductor 154.

The first amorphous silicon layer does not include impurities, and the second amorphous silicon layer includes conductive impurity ions.

Next, as shown in FIG. 16, after forming a conductive or metal layer on the substrate 100, the conductive or metal layer is patterned to form the source electrode 173 and the drain electrode 175.

Then, the ohmic contact pattern exposed between the source electrode and the drain electrode is removed using the source electrode 173 and the drain electrode 175 as a mask to form the ohmic contact 165.

Because the ohmic contact 165 is formed by patterning the ohmic contact pattern together with the semiconductor 154 and then, removing only the exposed ohmic contact pattern of the channel, the ohmic contact 165 has the same plane pattern as (i.e., follows the contours of) the semiconductor 154 excluding the channel.

Then, as shown in FIG. 14, the gate insulating layer 140 and the gate electrode 124 are formed on the source electrode 173 and the drain electrode 175.

The above TFT may be used as a TFT of an organic light emitting diode (OLED) display. Hereinafter, an OLED display including the TFT of FIGS. 1 and 2 will be described in more detail.

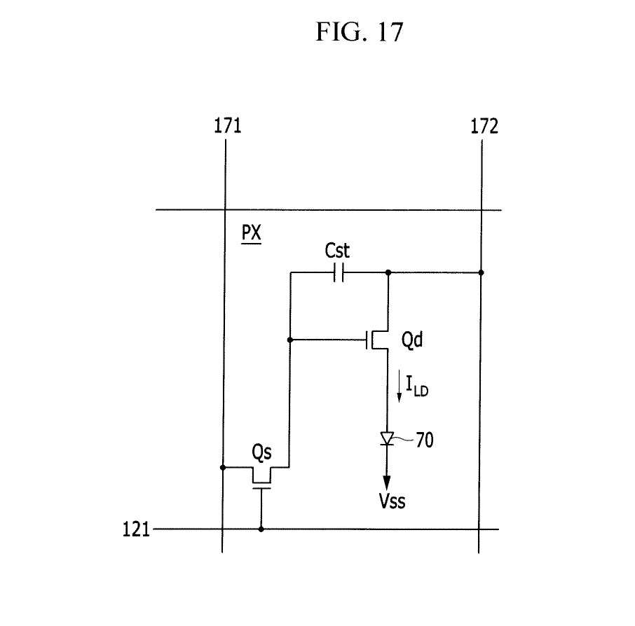

FIG. 17 is an equivalent circuit diagram of a pixel of an OLED display according to another embodiment.

As shown in FIG. 17, the OLED display according to the present embodiment includes a plurality of signal lines 121, 171, and 172 and a pixel PX coupled to the signal lines 121, 171, and 172. The pixel PX may be one of a red pixel (R), a green pixel (G), and a blue pixel (B).

The signal lines include the scanning signal line 121 for transmitting a gate signal (or a scan signal) 121, the data line 171 for transmitting a data signal, and the driving voltage line 172 for transmitting a driving voltage. The scanning signal lines 121 are parallel with each other in a row direction, and the data lines 171 are parallel with each other in a column direction. The driving voltage lines 172 are illustrated to be formed in a column direction, however, may be formed in a row or column direction or may be mesh-shaped.

The pixel PX includes a switching transistor Qs, a driving transistor Qd, a storage capacitor Cst, and an organic light emitting element 70.

The switching transistor Qs includes a control terminal, an input terminal, and an output terminal. The control terminal is coupled to the scanning signal line 121, the input terminal is coupled to the data line 171, and the output terminal is coupled to the driving transistor Qd. The switching transistor Qs transmits the data signal received from the data line 171 to the driving transistor Qd in response to the scan signal received from the scanning signal line 121.

The driving transistor Qd includes a control terminal, an input terminal, and an output terminal. The control terminal is coupled to the switching transistor Qs, the input terminal is coupled to the driving voltage line 172, and the output terminal is coupled to the organic light emitting element 70. The driving transistor Qd flows an output current ILD whose magnitude varies with a voltage between the control terminal and the output terminal.

The capacitor Cst is coupled between the control terminal and the input terminal of the driving transistor Qd. The capacitor Cst charges the data signal applied to the control terminal of the driving transistor Qd and maintains the data signal after the switching transistor Qd is turned off.

The organic light emitting element 70 as, for example, an organic light emitting diode (OLED) includes an anode coupled to the output terminal of the driving transistor Qd and a cathode coupled to a common voltage Vss. The organic light emitting element 70 emits light with intensity that varies with the output current ILD of the driving transistor Qd to display an image. The organic light emitting element 70 may include an organic material that emits light of one or at least one of primary colors such as red, green, and blue. The OLED display displays a desired image by the spatial sum of the above colors.

The switching transistor Qs and the driving transistor Qd are n-channel field effect transistors (FET). However, at least one of the switching transistor Qs and the driving transistor Qd may be a p-channel FET. In addition, a connection relationship among the transistors Qs and Qd, the capacitor Cst, and the organic light emitting element 70 may be changed.

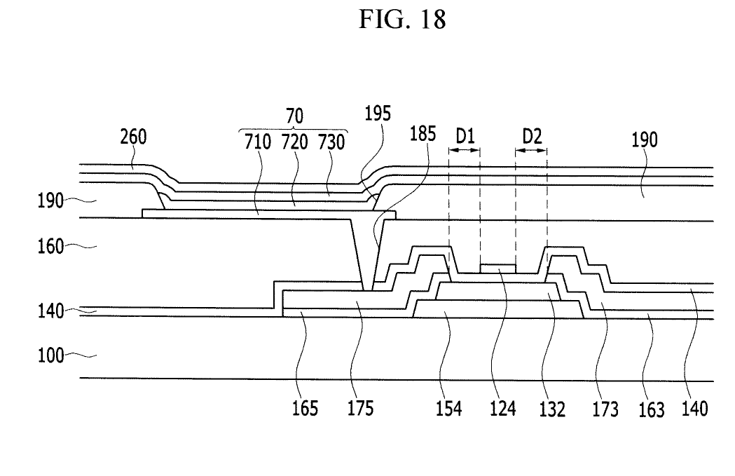

FIG. 18 is a cross-sectional view of a pixel of the OLED display of FIG. 17.

In FIG. 18, a lamination order of the driving TFT Qd and the organic light emitting element 70 of FIG. 17 will be described in detail. Hereinafter, the driving TFT Qd is referred to as a TFT.

As shown in FIG. 18, the semiconductor 154 formed of amorphous silicon is formed on the substrate 100.

The etch stop layer 132 is formed on the semiconductor 154. The etch stop layer 132 is formed of silicon nitride and overlaps the channel of the semiconductor 154.

The ohmic contacts 163 and 165 that contact the semiconductor 154 (and that face each other with the etch stop layer 132 interposed therebetween) are formed on the etch stop layer 132.

The ohmic contacts 163 and 165 may be formed of a material such as n+ amorphous silicon hydride highly doped with n-type impurities such as P or silicide.

The source electrode 173 and the drain electrode 175 are formed on the ohmic contacts 163 and 165.

The source electrode 173 and the drain electrode 175 have the same plane pattern as (i.e., follow the contours of) the ohmic contacts 163 and 165, respectively, and may be a single layer or a plurality of layers formed of a metal such as copper, aluminum, tungsten, titanium, or an alloy of the above metals.

The gate insulating layer 140 that covers the channel is formed on the source electrode 173 and the drain electrode 175. The gate insulating layer 140 may be formed of an inorganic layer such as silicon nitride or silicon oxide.

The gate electrode 124 is formed on the gate insulating layer 140 corresponding to the channel. The gate electrode 124 may be a single layer or a plurality of layers formed of the same metal or alloy as that of the source electrode 173 and the drain electrode 175.

The gate electrode 124 is positioned on the semiconductor 154 between the source electrode 173 and the drain electrode 175 that face each other.

A channel of the TFT is formed in the semiconductor 154 between the source electrode 173 and the drain electrode 175.

The gate electrode 124 and the source electrode 173 are laterally separated from each other by a second distance D2, and the gate electrode 124 and the drain electrode 175 are laterally separated from each other by a first distance D1 to form offsets.

An interlayer insulating layer 160 is formed on the gate electrode 124. The interlayer insulating layer 160 may be formed of tetra ethyl ortho silicate (TEOS), silicon nitride, or silicon oxide like the gate insulating layer 140.

The interlayer insulating layer 160 and the gate insulating layer 140 have a contact hole 185 that exposes the drain electrode 175.

A first electrode 710 coupled to the drain electrode 175 is formed on the interlayer insulating layer 160. The first electrode 710 becomes an anode electrode of the organic light emitting element of FIG. 17.

A pixel defining layer 190 (see FIG. 18) is formed on the first electrode 710.

The pixel defining layer 190 has an opening 195 that exposes the first electrode 710. The pixel defining layer 190 may be formed of a resin and silica based inorganic material such as polyacrylates or polyimides.

An organic light emitting layer 720 is formed in the opening 195 of the pixel defining layer 190.

The organic light emitting layer 720 is formed of a plurality of layers including a light emitting layer and further including at least one of a hole-injection layer (HIL), a hole-transporting layer (HTL), an electron-transporting layer (ETL), and an electron-injection layer (EIL).

When the organic light emitting layer 720 includes all of the light emitting layer, the HIL, the HTL, the ETL, and the EIL, the HIL may be positioned on the first electrode 710 that is the anode electrode and the HTL, the light emitting layer, the ETL, and the EIL may be sequentially laminated on the HIL.

A second electrode 730 is formed on the pixel defining layer 190 and the organic light emitting layer 720.

The second electrode 730 becomes a cathode electrode of the organic light emitting element 70 of FIG. 17. Therefore, the first electrode 710, the organic light emitting layer 720, and the second electrode 730 form the organic light emitting element 70.

The OLED display may be one of a front surface display type OLED display, a rear surface display type OLED display, and both surface display type OLED display in accordance with a direction in which the organic light emitting element 70 emits light.

In the front surface display type OLED display, the first electrode 710 is formed of a reflective layer, and the second electrode 730 is formed of a semi-transmissive layer. On the other hand, in the rear surface display type OLED display, the first electrode 710 is formed of a semi-transmissive layer, and the second electrode 730 is formed of a reflective layer. In the both surface display type OLED display, the first electrode 710 and the second electrode 730 are formed of a transparent layer or a semi-transmissive layer.

The reflective layer and the semi-transmissive layer are formed of at least one metal among Mg, Ag, Au, Ca, Li, Cr, and Al or an alloy of the above metals. The reflective layer and the semi-transmissive layer are determined by a thickness and the semi-transmissive layer may be formed to a thickness less than or equal to 200 nm. As a thickness is reduced, transmittance is increased. However, when the thickness is too small, resistance is increased.

The transparent layer is formed of a material such as indium tin oxide (ITO), indium zinc oxide (IZO), ZnO, or In₂O₃.

An encapsulation member 260 may be formed of an inorganic layer or an organic layer on the second electrode 730, and the inorganic layer and the organic layer may be alternately laminated. The encapsulation member 260 protects the pixel against external air.

At least one organic layer and at least one inorganic layer may be alternately laminated. The inorganic layer or the organic layer may be plural.

The organic layer is formed of polymer and may be a single layer or a laminated layer formed of one of polyethyeleneterepthalate (PET), polyimide, polycarbonate (PC), epoxy, polyethylene, and polyacrylate (PAR). The organic layer may be formed of polyacrylate (PC). To be specific, the organic layer includes a polymerized monomer composition including diacrylate monomer and triacrylate monomer. The monomer composition may further include monoacrylate monomer. In addition, the monomer composition may further include a suitable photo-initiator such as TPO but is not limited thereto.

The inorganic layer may be a single layer or a laminated layer including a metal oxide or a metal nitride. To be specific, the inorganic layer may include one of SiNx, Al₂O₃, SiO₂, and TiO₂.

In the encapsulation member 260, the uppermost layer exposed to the outside may be formed of the inorganic layer in order to prevent the organic light emitting element from being moist.

The encapsulation member 260 may include at least one sandwich structure in which at least one organic layer is inserted between at least two inorganic layers. In addition, the encapsulation member 260 may include at least one sandwich structure in which at least one inorganic layer is inserted between at least two organic layers.

A halogenated metal layer including LiF may be further included between the second electrode 730 and the inorganic layer. The halogenated metal layer may prevent or protect a display unit including the second electrode 730 from being damaged when the inorganic layer is formed by a sputtering method or a plasma deposition method.

The encapsulation member 260 may be replaced by an encapsulation substrate such as a metal substrate or a glass substrate instead of forming the organic layer and the inorganic layer.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims, and their equivalents.

1. A thin film transistor (TFT), comprising:
a semiconductor on a substrate;
an ohmic contact overlapping at least a portion of the semiconductor;
a source electrode and a drain electrode on the ohmic contact;
a gate insulating layer covering the semiconductor;
a gate electrode overlapping the semiconductor and between the source electrode and the drain electrode on the gate insulating layer,
wherein the gate electrode is laterally separated from the drain electrode by a first distance and is laterally separated from the source electrode by a second distance; and
an etch stop layer at the semiconductor between the ohmic contact and the semiconductor,
wherein the source electrode and the drain electrode follow a contour of the ohmic contact.

2. The TFT of claim 1, wherein the first distance and the second distance are no less than 0 μm and no more than 10 μm.

3. The TFT of claim 2, wherein the first distance and the second distance are no less than 0 μm and no more than 2 μm.

4. The TFT of claim 1, wherein
the etch stop layer is between the source electrode and the drain electrode.

5-6. (canceled)

7. An organic light emitting diode (OLED) display, comprising:
a substrate;
a TFT on the substrate;
a first electrode coupled to the TFT;
a light emitting layer on the first electrode; and
a second electrode on the light emitting layer,
wherein a gate electrode of the TFT is laterally separated from a drain electrode by a first distance and is laterally separated from a source electrode by a second distance,
wherein the TFT comprises:
a semiconductor on the substrate;
an ohmic contact overlapping at least a portion of the substrate; and
an etch stop layer at the semiconductor between the ohmic contact and the semiconductor,
wherein the source electrode and the drain electrode follow a contour of the ohmic contact.

8. The OLED display of claim 7, wherein the TFT comprises:
the source electrode and the drain electrode on the ohmic contact;
a gate insulating layer covering the semiconductor; and
the gate electrode overlapping the semiconductor between the source electrode and the drain electrode on the gate insulating layer.

9. The OLED display of claim 7, wherein the first distance and the second distance are no less than 0 μm and no more than 10 μm.

10. The OLED display of claim 9, wherein the first distance and the second distance are no less than 0 μm and no more than 2 μm.

11. The OLED display of claim 7, further comprising:
an encapsulation member on the second electrode, and
wherein the encapsulation member comprises at least one inorganic layer and at least one organic layer.
